(19) United States
(12) Patent Application Publication
(10) Pub. No.: US 2021/0288275 A1
(43) Pub. Date: Sep. 16, 2021

(54) FLEXIBLE SUBSTRATE, MANUFACTURING METHOD THEREOF, AND ORGANIC LIGHT EMITTING DISPLAY PANEL

(71) Applicant: Wuhan China Star Optoelectronics Semiconductor Display Technology Co., Ltd., Wuhan (CN)

(72) Inventor: Linbo KE, Wuhan (CN)

(73) Assignee: Wuhan China Star Optoelectronics Semiconductor Display Technology Co., Ltd., Wuhan (CN)

(21) Appl. No.: 16/625,765

(22) PCT Filed: Sep. 6, 2019
(86) PCT No.: PCT/CN2019/104627

§ 371 Date: Dec. 23, 2019

(30) Foreign Application Priority Data
Jul. 30, 2019 (CN) 201910693150.8

(51) Int. Cl. H01L 51/00; H01L 51/56

(52) U.S. Cl. CPC H01L 51/0097; H01L 2251/5338; H01L 51/56

(57) ABSTRACT

A flexible substrate, a manufacturing method thereof, and an organic light emitting display panel are provided. The flexible substrate includes at least one barrier layer and a plurality of organic material layers, the organic material layers and the barrier layers are configured to be alternately stacked in sequence, and main material of the barrier layer includes a mixture of amorphous silicon and silicon-based oxynitride SiₓO_{y}N_{z}. In this way, it can not only improve an adhesion force between the film layers of the flexible substrate, but also allow the flexible substrate to have better bending performance and high temperature and high humidity resistance.

### FIELD OF INVENTION

The application relates to the field of display technology, and in particular, to a flexible substrate, a manufacturing method thereof, and an organic light emitting display panel.

### BACKGROUND OF INVENTION

With the rapid development of modern display technology, the field of the display technology is developed in a direction of being light, thin, and flexible. In traditional display panels, glass substrates have high hardness and are easily broken, and, thus, are difficult to meet the development trend of the flexible display technology. However, film layer substrates made of polymer material have many advantages, such as light weight, flexibility and excellent comprehensive performance, to fully meet the requirements of the display technology on the flexibility. Therefore, the flexible polymer substrate is a development direction of the flexible display technology in the future.

Currently, the polymer material used for making the flexible substrate is generally polyimide (PI). The polyimide has excellent heat resistance, radiation resistance, chemical resistance, electrical insulation, etc., but its water blocking and oxygen blocking abilities are weak. Therefore, as using the polyimide to make the flexible substrate, an alternately stacked structure of a plurality of layers of the polyimide and inorganic silicon oxide (SiO₂) is generally used to achieve the water blocking and the oxygen blocking effects. However, an adhesion force between the polyimide and the inorganic silicon oxide is not enough, so separation between respective layers of the flexible substrate easily occurs in a high temperature and high humidity environment.

### TECHNICAL PROBLEM

Because the current flexible substrates exist in the high temperature and high humidity environment, the problem of the separation between respective layers of the flexible substrate easily occurs.

### SUMMARY OF INVENTION

The present disclosure provides a flexible substrate. The flexible substrate includes at least one barrier layer and a plurality of organic material layers. The organic material layers and the barrier layers are configured to be alternately stacked in sequence, and main material of the barrier layer includes a mixture of amorphous silicon and silicon-based oxynitride SiₓO_{y}N_{z}.

The present disclosure further provides an organic light emitting display panel including an organic light emitting device. The organic light emitting display panel also includes a flexible substrate. The flexible substrate includes at least one barrier layer and a plurality of organic material layers. The organic material layers and the barrier layers are configured to be alternately stacked in sequence, main material of the barrier layer includes a mixture of amorphous silicon and silicon-based oxynitride SiₓO_{y}N_{z}, and the organic light emitting device is disposed on the flexible substrate.

The present disclosure further provides a manufacturing method of a flexible substrate. The method includes: providing a substrate; forming a plurality of organic material layers and at least one barrier layer on the substrate, wherein the layer located on the substrate is the organic material layer, the organic material layers and the barrier layers are configured to be alternately stacked in sequence, and main material of the barrier layer includes a mixture of amorphous silicon and SiₓO_{y}N_{z}; and separating the substrate and the organic material layer thereon.

### ADVANTAGEOUS EFFECTS

The present disclosure provides the flexible substrate by means of configuring the organic layer and the barrier layer to be alternately stacked in sequence. The main material of the barrier layer includes the mixture of the amorphous silicon and the silicon-based oxynitride SiₓO_{y}N_{z}. Due to a small silicon atomic radius of the amorphous silicon, it is easy to be embedded in polyimide macromolecules to enhance an adhesion force between upper and lower layers. Moreover, polarity of a nitrogen atom and an oxygen atom of SiₓO_{y}N_{z} is large so that the adhesion force between the upper and lower organic thin films is further increased, thereby increasing the adhesion forces between the film layers of the flexible substrate, which is beneficial for avoiding the separation between the film layers to render the use of the flexible substrate stable.

### DESCRIPTION OF DRAWINGS

FIG. 1 is a structural schematic view of a first embodiment of a flexible substrate of the present disclosure.

FIG. 2 is a schematic view of a stripping test of the flexible substrate of the first embodiment of the present disclosure.

FIG. 3 is a schematic view of comparison between a permeation amount of water vapor of the flexible substrate of the first embodiment of the present disclosure and a permeation amount of water vapor of a flexible substrate in the prior art.

FIG. 4 is a structural schematic view of a second embodiment of a flexible substrate of the present disclosure.

FIG. 5 is a process diagram of an embodiment of a manufacturing method of a flexible substrate of the present disclosure.

### DETAILED DESCRIPTION OF PREFERRED EMBODIMENTS

In combination with accompanying drawings in embodiments of the present disclosure below, technical solutions of various exemplary embodiments provided by the present disclosure are clearly and completely described. In the absence of conflict, the following embodiments and their technical features can be combined with each other.

Directional terms described by the present disclosure, such as upper, lower, top, bottom, front, back, left, right, inner, outer, side, around, center, transverse, horizontal, longitudinal, vertical, radial, uppermost, lowermost, etc., are only directions by referring to the accompanying drawings. Therefore, the used directional terms are applied to describe and understand the present disclosure, but the present disclosure is not limited thereto.

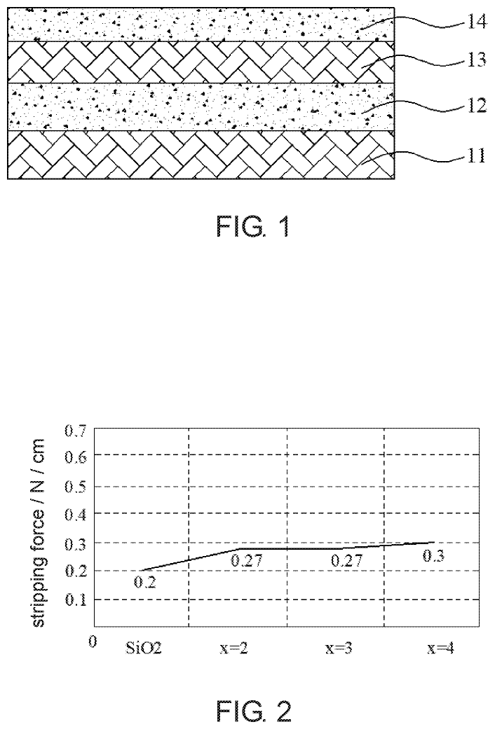

Referring to FIG. 1, a flexible substrate 10 provided by a first embodiment of the present disclosure includes at least one barrier layer and a plurality of organic material layer, and the organic material layers and the barrier layers are configured to be alternately stacked in sequence.

Specifically, the flexible substrate 10 provided by this embodiment may include two barrier layers and two organic material layers, and the two barrier layers and the two organic material layers are alternately stacked in sequence.

The two organic material layers are respectively a first organic material layer 11 and a second organic material layer 13, the two barrier layers are respectively a first barrier layer 12 and a second barrier layer 14, and they are alternately stacked in accordance with a way of the first organic material layer 11, the first barrier layer 12, the second organic material layer 13, and the second barrier layer 14, in which:

Material used for the first organic material layer 11 and the second organic material layer 13 may be the same or be different. In this embodiment, the material preferably used for the first organic material layer 11 and the second organic material layer 13 is polyimide. The polyimide has excellent heat resistance, radiation resistance, chemical resistance, electrical insulation, mechanical property, etc. The flexible substrate made of the polyimide enables the flexible substrate to have sufficient heat resistance and flexibility. In this embodiment, the material of the first organic material layer 11 and the material of the second organic material layer 13 are the same, and employ the polyimide material, thereby not only facilitating production, but also rendering performance of the flexible substrate 10 stable.

In the prior art, production of the flexible substrate only employs the polyimide. However, water blocking and oxygen blocking abilities of the polyimide are weak. An alternately disposed structure of a plurality of layers of the polyimide and inorganic silicon oxide (SiO₂) is used as an improvement way, but separation between the film layers of the flexible substrate formed by the polyimide and the inorganic silicon oxide occurs at high temperature and high humidity. Therefore, a new solution is provided in this embodiment.

In this embodiment, a new material used for the first barrier layer 12 and the second barrier layer 14 is substituted for the single inorganic silicon dioxide material. Specifically, the main material of the first barrier layer 12 and the second barrier layer 14 includes a mixture of amorphous silicon and silicon-based oxynitride SiₓO_{y}N_{z}.

The amorphous silicon (α-Si) is also called a non-crystalline form of silicon, and is the form of elemental silicon. Chemical properties of the amorphous silicon are more active than that of crystalline silicon. The amorphous silicon is a commonly used semiconductor material that can be deposited on a variety of substrates in the form of thin film to provide unique properties for a variety of electronic devices. Due to a small atomic radius of the α-Si, it is easy to be embedded in the polyimide macromolecules to enhance an adhesion force between upper and lower layers.

The silicon-based oxynitride SiₓO_{y}N_{z} has desirable chemical stability, thermal stability, mechanical properties and a passivation property, and also has excellent photoelectric properties. It is an ideal dielectric film.

The silicon-based oxynitride SiₓO_{y}N_{z} is obtained by gas material containing element nitrogen (such as N₂O or N₂O plus NH₃) reacting with silane gases (SiH₄). In a plasma-enhanced condition and a heated environment, the generated silicon-based oxynitride contains three elements of silicon, oxygen, and nitrogen. Generally, the silicon-based oxynitride SiₓO_{y}N_{z} is achieved by a plasma chemical vapor deposition method, a physical vapor deposition method, or an oxide film method of high temperature silicon nitride.

Si—O—N thin films formed by the silicon-based oxynitride SiₓO_{y}N_{z} have a desirable passivation property for water and oxygen leakage, and can block water and oxygen permeation in the flexible substrate 10. Moreover, the Si—O—N thin films have a tetrahedral structure, Si atoms occupy a center of the tetrahedron, and N atoms and O atoms are located at corners of the tetrahedron. Due to a large polarity of the N atom and the O atom, bonding tightness of molecules of the upper and lower layers is increased.

Therefore, the mixture of the α-Si and the silicon-based oxynitride SiₓO_{y}N_{z} is used for replacing the silicon oxide, which not only enhances the adhesion forces between the film layers, but also improves the performance of water blocking and oxygen blocking.

Specifically, in this embodiment, atomic numbers of x, y, and z of the elements of Si, O, and N are integrals, a value of x ranges from 1 to 4, and 2y+3z=4x. For exale, the SiₓO_{y}N_{z} can be Si₂O₁N₂, Si₃O₃N₂, or Si₄O₅N₂. When x, y, and z are taken as different values, the adhesion forces between the film layers of the flexible substrate 10 are affected. With the increase of x, y, and z, the adhesion forces between the film layers of the flexible substrate 10 gradually increase, and a stripping force between the film layers gradually increases as well, specifically referring to FIG. 2.

Furthermore, in this embodiment, a thickness of the second organic material layer 13 is less than or equal to the first organic material layer 11 to ensure both toughness and flexibility.

In this embodiment, the second barrier layer 14 is disposed on the second organic material layer 13, and is used as a carrying surface of the flexible substrate 10. The flexible substrate 10 of this embodiment can be used for carrying substrates of display devices, such as organic light emitting display devices, LCD, and Micro-LED.

A thickness of the first barrier layer 12 ranges from 100 to 650 nm, and the thickness of the first barrier layer 12 may be the same as a thickness of the second barrier 14, which is between 100 and 650 nm to ensure the flexibility and the toughness of the flexible substrate 10, while the second barrier layer 14 is configured to allow the sufficient adhesion forces between the film layers. By using the mixture of the α-Si and the SiₓO_{y}N_{z} as the barrier film layer, not only are the adhesion forces between the film layers elevated at least 150% but also the flexible substrate with excellent bending performance and high temperature and high humidity resistance can be achieved.

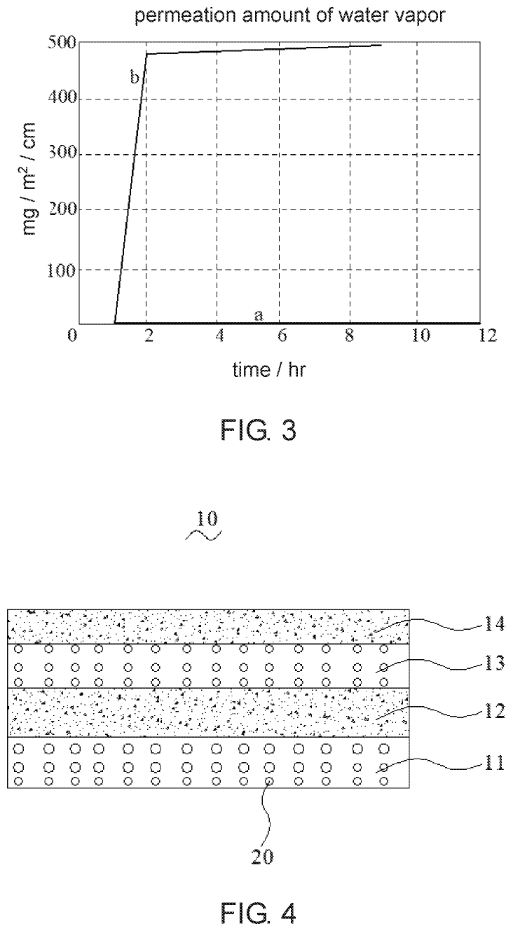

Referring to FIG. 3, there is a schematic view of comparison between a permeation amount of water vapor of the flexible substrate of the first embodiment and a permeation amount of water vapor of a flexible substrate in the prior art, and wherein a is a linear representation of the permeation amount of water vapor of the flexible substrate of this embodiment, and b is a linear representation of the permeation amount of water vapor of the flexible substrate of the prior art. The flexible substrate 10 provided by this embodiment has a lower permeation rate compared to the flexible substrate with the barrier layer made of single material. A permeation rate of the flexible substrate with the barrier layer made of single material is 500 mg/m2/day, whereas the permeation rate of the flexible substrate 10 of this embodiment is decreased to 0.05 mg/m2/day to allow the permeation rate to be significantly reduced. Using the barrier layer with the mixture of the amorphous silicon and the silicon-based oxynitride SiₓO_{y}N_{z} not only elevates the adhesion forces between the film layers, but also reduces the permeation rate of the entire flexible substrate, so that the display panels manufactured by these flexible substrates prolong service lifespan and enhance durability.

In the above-mentioned flexible substrate 10, the flexible substrate 10 is configured by alternately stacking the organic material layers and the barrier layers in sequence. The main material of the barrier layer includes the mixture of the amorphous silicon and the silicon-based oxynitride SiₓO_{y}N_{z}. Due to the small Si atomic radius of the amorphous silicon, it is easy to be embedded in the polyimide macromolecules. Moreover, the polarity of the N atom and the O atom of SiₓO_{y}N_{z} is large, so that the adhesion force between the upper and lower organic film layers is further increased. And the Si—O—N thin films formed by the silicon-based oxynitride SiₓO_{y}N_{z} have the desirable passivation property for water and oxygen leakage, and can block water and oxygen permeation to interior of the flexible substrate 10. By using the amorphous silicon and the silicon-based oxynitride SiₓO_{y}N_{z} as the barrier layers, the adhesion forces between the film layers of the flexible substrate 10 are increased, and the performance of water and oxygen blocking is improved, thus rendering the flexible substrate 10 stable.

Referring to FIG. 4, there is a flexible substrate 10 provided by a second embodiment of the present disclosure. The flexible substrate 10 of this embodiment is substantially the same as the flexible substrate 10 of the first embodiment, except that:

At least one of the organic material layers and the barrier layers is doped with a water absorbing material 20.

In order to improve a water absorbing performance of the flexible substrate 10, the water absorbing material 20 can be added to each of the organic material layers, or each of the barrier layers, or to each of the organic material layers and each of the barrier layers.

Preferably, in this embodiment, the water absorbing material 20 is added to each of the organic material layers, that is, the water absorbing material 20 is added to the first organic material layer 11 and the second organic material layer 13. The first organic material layer 11 and the second organic material layer 13 include organic matrix and the water absorbing material 20 distributed in the organic matrix.

Furthermore, the water absorbing material 20 may be one or more of calcium oxide, magnesium sulfate, calcium sulfate, aluminum oxide, and barium oxide. Preferably, in this embodiment, the water absorbing material 20 is calcium oxide. The calcium oxide is a white powder, is sensitive to humidity, and easily absorbs water, so that an effect of actively absorbing the water vapor which is mixed in the organic material layers during manufacturing processes can be achieved. Moreover, after the calcium oxide absorbs the water, a part of oxygen dissolving in the water is incapable of moving, and reduces a rate of movement, thus further achieving an effect of blocking the oxygen. Furthermore, anhydrous magnesium sulfate, calcium sulfate, aluminum oxide and cerium oxide are also commonly used as chemical drying reagents with white color. After the anhydrous magnesium sulfate, calcium sulfate, aluminum oxide, and cerium oxide absorb the moisture, the colors, particle diameters, and material properties do not significantly influence the flexible substrate as well. Thus, all of the anhydrous magnesium sulfate, calcium sulfate, aluminum oxide, and cerium oxide may be used. Therefore, in other embodiments, a combination of various water absorbing materials may be used, so that the water absorbing materials, which have slightly different water absorbing properties, complement to each other, thereby rendering the effect of water absorbing desirable.

Furthermore, the water absorbing material 20 is distributed in the form of particles in the matrix of the organic material layer. Its particle diameter is on an order of nanometers, that is, the particle diameter of the calcium oxide is on the order of nanometers and ranges from a few nanometers to several hundred nanometers.

The distribution of concentration of the water absorbing material 20 in the second organic material layer 13 and the first organic material 11 can be disordered or ordered. Specifically, in this embodiment, the concentration of the water absorbing material in each layer of the second organic material layer 13 and the first organic material 11 is uniform, and the particle size is uniform, so that the flexible substrate 10 maintains sufficient flexibility.

In the above-mentioned flexible substrate 10, by doping the water absorbing material 20 in at least one of the organic material layers and the barrier layers, the water absorbing material 20 absorbs the water vapor which is mixed in the flexible substrate 10 during the manufacturing processes or during use to allow the flexible substrate 10 to be stable during use.

The flexible substrate 10 provided by the present disclosure can be the carrying substrates of the display devices, such as the organic light emitting display devices, the LCD, and the Micro-LED.

In the following specific embodiment, an organic light emitting display panel is taken as an illustration.

The organic light emitting display panel includes the above-mentioned flexible substrate and the organic light emitting display device, and the flexible substrate serves as the carrying plate to bear the organic light emitting display device.

Further, when the above-mentioned flexible substrate serves as the carrying plate of the organic light emitting display device, the thickness of the first barrier layer is between 100 and 650 nm. In this thickness range, the first barrier layer maintains not only the stability and the flexibility of the entire flexible substrate but also the sufficient performance of water and oxygen blocking. Preferably, in this embodiment, the thickness of the barrier layer may be 300 nm, so that the entire flexible substrate keeps thin enough and maintains the flexibility.

When the above-mentioned organic light emitting display panel is specifically manufactured, a hard substrate, such as a glass substrate and a rigid substrate, is provided first to be used as a carrier for manufacturing the flexible substrate. Specifically, the substrate is sprayed by using a spray method to form the first organic material layer in the form of film. After the first organic material layer is formed into the film, the first barrier layer is formed by spraying, the second organic material layer is formed by spraying on the first barrier layer, and the second barrier layer is finally formed by spraying on the second organic material layer. In the end, the entire spraying layer is cured to be shaped.

After completing the manufacturing of the above-mentioned flexible substrate, the production of the organic light emitting display panel is completed after thin film transistors and the organic light emitting display device are manufactured on the flexible substrate. Furthermore, in order to ensure the use stability of the organic light emitting display panel, a packaging thin film is manufactured on the organic light emitting display device to block invasion of water and oxygen to ensure the service lifespan of the entire organic light emitting display device.

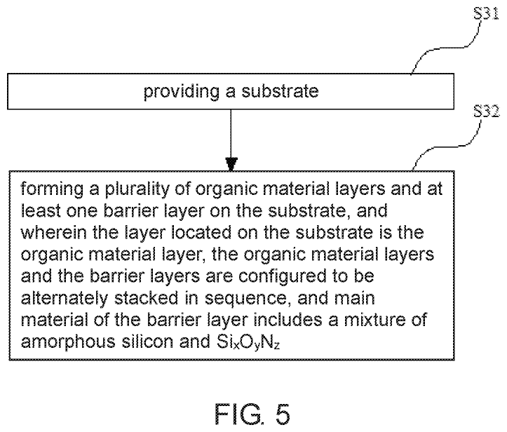

Referring to FIG. 5, there is a manufacturing method of the flexible substrate provided by a third embodiment of the present disclosure, and the method includes step S31 and step S32.

The step of S31 is providing a substrate.

The substrate is a hard substrate and may be a polymer material substrate, such as an acrylic or glass substrate, or a rigid substrate. The substrate is used to manufacture a carrying plate of the flexible substrate, and the substrate is sprayed to form a multi-layer film to form the flexible substrate.

The step of S32 is forming a plurality of organic material layers and at least one barrier layer on the substrate. The layer located on the substrate is the organic material layer, the organic material layers and the barrier layers are configured to be alternately stacked in sequence, and main material of the barrier layer includes a mixture of amorphous silicon and silicon-based oxynitride SiₓO_{y}N_{z}.

In this embodiment, the organic material layers include a first organic material layer and a second organic material layer, the at least one barrier layer includes a first barrier layer and a second barrier layer, and the first organic material layer, the first barrier layer, the second organic material layer, and the second barrier layer are alternately stacked in sequence.

During the specific manufacturing, a spray method is used and includes the following processes. The first organic material layer is formed on the substrate, and the first barrier layer is formed on the first organic material layer. After forming the first barrier layer, the second organic material layer is formed on a surface of the first barrier layer, and the second barrier layer is finally formed on the second organic material layer.

Further, the material of each of the organic material layers can be the same or different. For example, polyimide organic macromolecules material can be used at the same time. The material of the first barrier and the second barrier layer is mainly the mixture of the amorphous silicon and the silicon-based oxynitride SiₓO_{y}N_{z}.

The amorphous silicon (α-Si) is also called a non-crystalline form of silicon, and is the form of elemental silicon. Chemical properties of the amorphous silicon are more active than that of crystalline silicon. The amorphous silicon is a commonly used semiconductor material that can be deposited on a variety of substrates in the form of thin film to provide unique properties for a variety of electronic devices. Due to a small atomic radius of the α-Si, it is easy to be embedded in the polyimide macromolecules to enhance an adhesion force between upper and lower layers.

The silicon-based oxynitride SiₓO_{y}N_{z} has desirable chemical stability, thermal stability, mechanical properties and a passivation property, and also has excellent photoelectric properties. It is an ideal dielectric film.

The silicon-based oxynitride SiₓO_{y}N_{z} is obtained by gas material containing element nitrogen (such as N₂O or N₂O plus NH₃) reacting with silane gases (SiH₄). In a plasma-enhanced condition and a heated environment, the generated silicon-based oxynitride contains three elements of silicon, oxygen, and nitrogen. Generally, the silicon-based oxynitride SiₓO_{y}N_{z} is achieved by a plasma chemical vapor deposition method, a physical vapor deposition method, or an oxide film method of high temperature silicon nitride.

Si—O—N thin films formed by the silicon-based oxynitride SiₓO_{y}N_{z} have a desirable passivation property for water and oxygen leakage, and can block water and oxygen permeation in the flexible substrate 10. Moreover, the Si—O—N thin films have a tetrahedral structure, Si atoms occupy a center of the tetrahedron, and N atoms and O atoms are located at corners of the tetrahedron. Due to a large polarity of the N atom and the O atom, bonding tightness of molecules of the upper and lower layers is increased.

Therefore, the mixture of the α-Si and the silicon-based oxynitride SiₓO_{y}N_{z} is used for replacing silicon oxide, which not only enhances the adhesion forces between the film layers, but also improves the performance of water blocking and oxygen blocking.

Specifically, in this embodiment, atomic numbers of x, y, and z of the elements of Si, O, and N are integrals, a value of x ranges from 1 to 4, and 2y+3z=4x.

Further, in order to improve the performance of water and oxygen blocking, a water absorbing material can be added to a certain organic material layer or a certain barrier layer, or the water absorbing material can be added to each of the organic material layers and the barrier layers.

The water absorbing material may be one or more of calcium oxide, magnesium sulfate, calcium sulfate, aluminum oxide, and barium oxide. All of calcium oxide, magnesium sulfate, calcium sulfate, aluminum oxide, and barium oxide have a strong property of water absorbing, and do not affect the performance of the flexible substrate after absorbing the water.

After the manufacturing of the flexible substrate is completed, the hard substrate and the flexible substrate are separated. Specifically, the separation method can be one of a mechanical lift-off and a laser lift-off, or a combination of them.

The method of laser lift-off is to apply a high-intensity laser to an interface where the flexible substrate and the hard glass substrate are bonded, and is to ablate the polymer of the interface layer, thereby achieving the stripping of the flexible substrate and the hard glass. The method of laser lift-off is convenient and stable, and allows the complete stripping.

The method of mechanical lift-off is to apply a mechanical force to separate the flexible substrate and the rigid substrate, and it is a most original stripping method.

In other embodiments, new stripping techniques can also be used, such as using a method of chemical etching a stainless-steel substrate, using a resistive heating detachment technology, or using a method of embedding a second rigid substrate between the flexible substrate and the hard substrate.

In the above-mentioned manufacturing method of the flexible substrate, the flexible substrate is formed on the substrate, and the flexible substrate is configured by alternately stacking the organic material layers and the barrier layers in sequence. The main material of the barrier layer includes the mixture of the amorphous silicon and the silicon-based oxynitride SiₓO_{y}N_{z}. By using the amorphous silicon and the silicon-based oxynitride SiₓO_{y}N_{z} as the barrier layers, the atoms of Si, O, and N increase the adhesion force between the upper and lower layers to render the flexible substrate stable.

Although the present disclosure has been shown and described with respect to one or more of the embodiments, those skilled in the art will consider the equivalent variations and modifications based on reading and understanding of this specification and the accompanying drawings. The present disclosure includes all of these modifications and variations, and is only limited by the scope of the appended claims. In particular, regarding various functions performed by above-mentioned components, the terms used to describe such components are intended to correspond to any component (except for additional indication) that performs the specified functions of the components (for example, their functions are equivalent), even if the structure is not identical to the disclosed structure that performs the functions in the exemplary embodiments of this specification as illustrated herein. Additionally, although the specific features of this specification have been disclosed with respect to only one of several embodiments, such features can be combined with one or more other features of other embodiments that may be desirable and advantageous for a given or particular application. Moreover, in terms of the terms “include”, “including”, “have”, “having”, “contain”, “containing”, or their variants being used in the specific embodiments or claims, such terms are intended to be encompassed in a manner similar to the term “comprise”. Furthermore, it should be appreciated that “plurality” as referred to herein means two or more. For the steps mentioned herein, the numerical suffix is only for the purpose of clearly illustrating the embodiments to easily understand, it does not completely represent the order of practice of the steps, and it should be set in consideration of the logical relationship.

The above description is only the embodiments of the present disclosure, and thus it does not limit the patent scope of the present disclosure. The variations of the equivalent structure or the equivalent processes made by the description of the specification and the accompanying drawings of the present disclosure, for example, the technical features of the various embodiments are combined with each other, or directly or indirectly used in other related technical fields, are completely included in the scope of the patent protection of the present disclosure.

What is claimed is:

1. A flexible substrate, comprising:
at least one barrier layer; and
a plurality of organic material layers;
wherein the organic material layers and the barrier layers are configured to be alternately stacked in sequence, and main material of the barrier layer includes a mixture of amorphous silicon and silicon-based oxynitride SiₓO_{y}N_{z}.

2. The cover board according to claim 1, wherein all of x, y, and z are integrals, a value of x ranges from 1 to 4, and 2y+3z=4x.

3. The flexible substrate according to claim 1, wherein the organic material layers include a first organic material layer and a second organic material layer, and the at least one barrier layer includes a first barrier layer, wherein the first organic material layer, the first barrier layer, and the second organic material layer are alternately stacked in sequence, and a thickness of the second organic material layer is less than or equal to a thickness of the first organic material layer.

4. The flexible substrate according to claim 3, wherein the flexible substrate further includes a second barrier layer disposed on the second organic material layer, and the second barrier layer is used as a carrying surface of the flexible substrate.

5. The flexible substrate according to claim 3, wherein a thickness of the first barrier layer is between 100 nm and 650 nm.

6. The flexible substrate according to claim 1, wherein at least one of the organic material layers and the barrier layers is doped with a water absorbing material.

7. An organic light emitting display panel including an organic light emitting device, further comprising:
a flexible substrate including:
at least one barrier layer; and
a plurality of organic material layers;
wherein the organic material layers and the barrier layers are configured to be alternately stacked in sequence, main material of the barrier layer includes a mixture of amorphous silicon and silicon-based oxynitride SiₓO_{y}N_{z}, and the organic light emitting device is disposed on the flexible substrate.

8. The organic light emitting display panel according to claim 7, wherein all of x, y, and z are integrals, a value of x ranges from 1 to 4, and 2y+3z=4x.

9. The organic light emitting display panel according to claim 7, wherein the organic material layers include a first organic material layer and a second organic material layer, and the at least one barrier layer includes a first barrier layer, wherein the first organic material layer, the first barrier layer, and the second organic material layer are alternately stacked in sequence, and a thickness of the second organic material layer is less than or equal to a thickness of the first organic material layer.

10. The organic light emitting display panel according to claim 9, wherein the flexible substrate further includes a second barrier layer disposed on the second organic material layer, and the second barrier layer is used as a carrying surface of the flexible substrate.

11. The organic light emitting display panel according to claim 9, wherein a thickness of the first barrier layer is between 100 nm and 650 nm.

12. The organic light emitting display panel according to claim 7, wherein at least one of the organic material layers and the barrier layers is doped with a water absorbing material.

13. A manufacturing method of a flexible substrate, comprising:
providing a substrate;
forming a plurality of organic material layers and at least one barrier layer on the substrate, wherein the layer located on the substrate is the organic material layer, the organic material layers and the barrier layers are configured to be alternately stacked in sequence, and main material of the barrier layer includes a mixture of amorphous silicon and SiₓO_{y}N_{z}; and
separating the substrate and the organic material layer thereon.

14. The manufacturing method of the flexible substrate according to claim 13, wherein all of x, y, and z are integrals, a value of x ranges from 1 to 4, and 2y+3z=4x.

15. The manufacturing method of the flexible substrate according to claim 13, wherein the forming of the organic material layers and the at least one barrier layer on the substrate includes:
forming a first organic material layer on the substrate;
forming a first barrier layer on the first organic material layer;
forming a second organic material layer on the first barrier layer; and
forming a second barrier layer on the second organic material layer.

16. The manufacturing method of the flexible substrate according to claim 15, wherein a thickness of the second organic material layer is less than or equal to a thickness of the first organic material layer.

17. The manufacturing method of the flexible substrate according to claim 15, wherein a thickness of the first barrier layer is between 100 nm and 650 nm.

18. The manufacturing method of the flexible substrate according to claim 13, wherein at least one of the organic material layers and the barrier layers is doped with a water absorbing material.
